(19) United States
(12) Patent Application Publication
(10) Pub. No.: US 2024/0096876 A1
(43) Pub. Date: Mar. 21, 2024

(54) SEMICONDUCTOR DEVICE

(71) Applicants: Kabushiki Kaisha Toshiba, Tokyo (JP); Toshiba Electronic Devices & Storage Corporation, Tokyo (JP)

(72) Inventors: Takahiro NAKAGAWA, Kawasaki Kanagawa (JP); Kazuya NISHIHORI, Tokyo (JP); Yasuhiko KURIYAMA, Yokohama Kanagawa (JP)

(21) Appl. No.: 18/178,816

(22) Filed: Mar. 6, 2023

(30) Foreign Application Priority Data
Sep. 15, 2022 (JP) 2022-147306

(51) Int. Cl. H01L 27/06; H01L 23/498

(52) U.S. Cl. CPC H01L 27/0629; H01L 23/498

(57) ABSTRACT

According to one embodiment, a semiconductor device includes a plurality of transistors. The transistors are coupled through serial coupling. The transistors include a first transistor and a second transistor. The semiconductor device further includes a third transistor and a first diode. The second transistor includes a first sub-transistor and a second sub-transistor that are coupled in parallel with each other. The first transistor, the first sub-transistor, the second sub-transistor, the third transistor, and the first diode are arranged on a substrate, with the third transistor interposed between the first sub-transistor and the second sub-transistor in a first direction.

### CROSS-REFERENCE TO RELATED APPLICATIONS

This application is based upon and claims the benefit of priority from Japanese Patent Application No. 2022-147306, filed Sep. 15, 2022, the entire contents of which are incorporated herein by reference.

### FIELD

Embodiments described herein relate generally to a semiconductor device.

### BACKGROUND

Switch circuits used for portable terminals and the like have been known.

### BRIEF DESCRIPTION OF THE DRAWINGS

FIG. 1 is a block diagram for showing an exemplary configuration of a wireless device including a switch circuit according to the first embodiment.

FIG. 2 is a diagram for showing an exemplary circuitry configuration of the switch circuit according to the first embodiment.

FIG. 3 is a plan view for providing an overview of the arrangement of transistors included in the switch circuit according to the first embodiment.

FIG. 4 is a plan view for explaining the basic structure of a transistor included in the switch circuit according to the first embodiment.

FIG. 5 is a plan view for explaining the basic structure of a transistor included in the switch circuit according to the first embodiment.

FIG. 6 is a plan view for explaining the basic structure of a transistor included in the switch circuit according to the first embodiment.

FIG. 7 is a table showing combinations of types of transistors implemented on the switch circuit according to the first embodiment.

FIG. 8 is a plan view for showing a partial planar layout of a switch circuit in pattern 1 according to the first embodiment.

FIG. 9 is a plan view for showing a partial planar layout of a switch circuit in pattern 2 according to the first embodiment.

FIG. 10 is a plan view for showing a partial planar layout of a switch circuit in pattern 3 according to the first embodiment.

FIG. 11 is a plan view for showing a partial planar layout of a switch circuit in pattern 4 according to the first embodiment.

FIG. 12 is a plan view for providing an overview of the arrangement of transistors included in a switch circuit according to the second embodiment.

FIG. 13 is a plan view for showing a partial planar layout of a switch circuit in pattern 1 according to the second embodiment.

FIG. 14 is a plan view for showing a partial planar layout of a switch circuit in pattern 2 according to the second embodiment.

FIG. 15 is a plan view for showing a partial planar layout of a switch circuit in pattern 3 according to the second embodiment.

FIG. 16 is a plan view for showing a partial planar layout of a switch circuit in pattern 4 according to the second embodiment.

### DETAILED DESCRIPTION

In general, according to one embodiment, a semiconductor device includes an input terminal, an output terminal, and a plurality of transistors. The transistors are coupled through serial coupling between the input terminal and the output terminal. The transistors include a first transistor and a second transistor. The first transistor has a first end and a second end that are used for the serial coupling. The second transistor has a third end, a fourth end, a first gate, and a first body. The third end and the fourth end are used for the serial coupling. The third end is coupled to the second end. The semiconductor device further includes a third transistor and a first diode. The third transistor and the first diode are serially coupled between the first body and the first end. The third transistor includes a second gate coupled to the first gate. An anode of the first diode is arranged on a side of the first body between the first body and the first end. The second transistor includes a first sub-transistor and a second sub-transistor that are coupled in parallel with each other. The first transistor, the first sub-transistor, the second sub-transistor, the third transistor, and the first diode are arranged on a substrate, with the third transistor interposed between the first sub-transistor and the second sub-transistor in a first direction.

The embodiments will be explained below with reference to the drawings. In the following description, the same reference numerals are assigned to structural components having the same functions and structures. When structural components with the same reference numerals need to be distinguished from one another, indices may be attached to the numerals. If the structural components do not need to be particularly distinguished, the components will be given the reference numerals only, without any index.

### <1> First Embodiment

A semiconductor device according to the first embodiment will be described below. Hereinafter, the semiconductor device may also be referred to as a switch circuit 1.

### <1-1> Configuration

### <1-1-1> Wireless Device

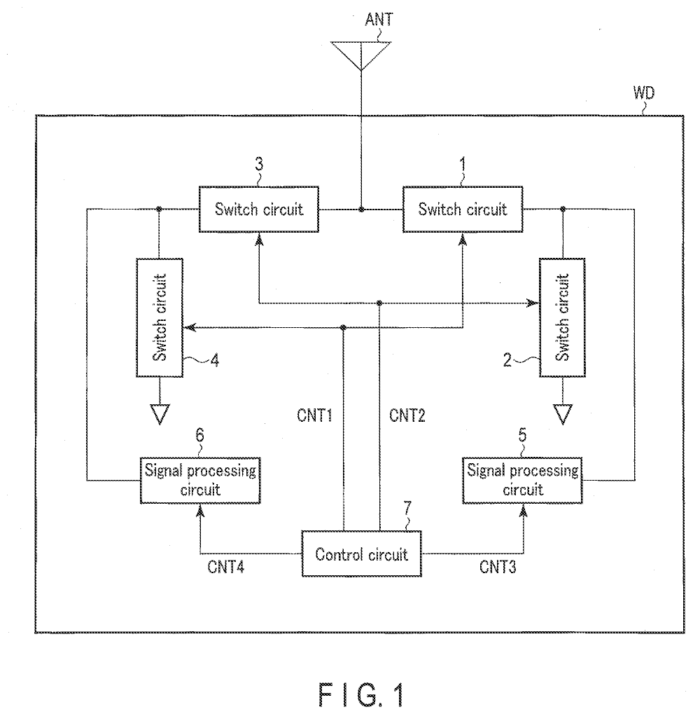

FIG. 1 is a block diagram for showing an exemplary configuration of a wireless device WD including the switch circuit 1 according to the first embodiment. The wireless device WD may be a smartphone, a feature phone, a portable terminal (e.g., tablet terminal), a personal computer, a game machine, a router, or a base station. The wireless device WD transmits and receives signals using communication standards such as Long Term Evolution (LTE (trademark)) and/or Wi-Fi.

In addition to the switch circuit 1, the wireless device WD may include an antenna ANT, switch circuits 2, 3, and 4, signal processing circuits 5 and 6, and a control circuit 7.

The antenna ANT receives high-frequency signals from other devices (e.g., a base station and other wireless devices). The antenna ANT may also transmit high-frequency signals from the wireless device WD to other devices.

The control circuit 7 may transmit a control signal CNT to the switch circuits 1, 2, 3, and 4 and also to the signal processing circuits 5 and 6. Whether each of the switch circuits 1, 2, 3, and 4 is in an ON state or OFF state is controlled by the control signal CNT that the respective switch circuit receives from the control circuit 7. During the ON state of a switch circuit, this switch circuit can convey a signal between the first end and the second end of the switch circuit. On the other hand, during the OFF state of the switch circuit, this switch circuit conveys no signal between the first end and second end of the switch circuit. Each of the signal processing circuits 5 and 6 performs signal processing based on the control signal CNT received from the control circuit 7.

The first end of the switch circuit 1 is coupled to the antenna ANT, while the second end of the switch circuit 1 is coupled to the signal processing circuit 5. The switch circuit 1 receives a control signal CNT1 from the control circuit 7. While in the ON state based on the control signal CNT1, the switch circuit 1 transfers a high-frequency signal received by the wireless device WD via the antenna ANT to the signal processing circuit 5.

The first end of the switch circuit 2 is coupled to the signal path between the switch circuit 1 and the signal processing circuit 5. The second end of the switch circuit 2 may be grounded.

The switch circuit 2 receives a control signal CNT2 from the control circuit 7. For instance, when the switch circuit 1 is in the OFF state, the switch circuit 2 is in the ON state based on the control signal CNT2. While in the ON state, the switch circuit 2 maintains the potential of a signal path between the switch circuit 1 and signal processing circuit 5 at the ground potential.

The signal processing circuit 5 receives a high-frequency signal transferred via the switch circuit 1, and executes various kinds of processing upon the high-frequency signal, based on the control signal CNT3 received from the control circuit 7.

The first end of the switch circuit 3 is coupled to the antenna ANT, while the second end of the switch circuit 3 is coupled to the signal processing circuit 6. The switch circuit 3 receives, for example, a control signal CNT2 from the control circuit 7. While in the ON state based on the control signal CNT2, the switch circuit 3 may transfer a high-frequency signal received by the wireless device WD via the antenna ANT to the signal processing circuit 6. The frequency band of the high-frequency signal transferred by the switch circuit 3 differs, for example, from the frequency band of the high-frequency signal transferred by the switch circuit 1. The switch circuit 1 and switch circuit 3 may be selectively turned to the ON state under the control of the control circuit 7.

The first end of the switch circuit 4 is coupled to the signal path between the switch circuit 3 and the signal processing circuit 6. The second end of the switch circuit 4 may be grounded. The switch circuit 4 receives a control signal CNT1 from the control circuit 7. For instance, with the switch circuit 3 being in the OFF state, the switch circuit 4 is in the ON state in response to the control signal CNT1. While in the ON state, the switch circuit 4 maintains the potential of the signal path between the switch circuit 3 and signal processing circuit 6 at the ground potential.

The signal processing circuit 6 receives a high-frequency signal transferred via the switch circuit 3, and executes various kinds of processing upon the high-frequency signal based on the control signal CNT4 received from the control circuit 7.

In the above description, the switch circuits 1 and 3 respectively transfer a high-frequency signal that the wireless device WD receives from other devices. The switch circuits 1 and 3 are not limited thereto. The switch circuits 1 and 3 may respectively transfer a high-frequency signal to be transmitted by the wireless device WD to other devices.

The following description will focus on the switch circuit 1.

### <1-1-2> Switch Circuit

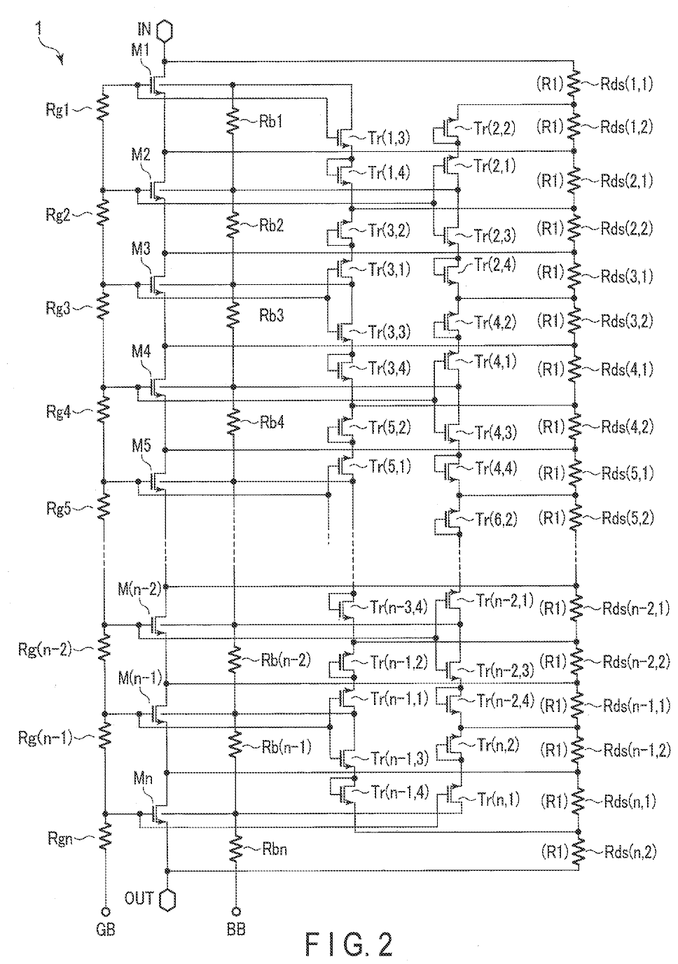

FIG. 2 shows an exemplary circuitry configuration of the switch circuit 1 according to the first embodiment. According to the circuit symbol of each transistor in FIG. 2, one end of the transistor is illustrated as a drain and the other end thereof is illustrated as a source. The drain and source, however, may be interchanged in accordance with the relationship between the potentials at the two ends.

The switch circuit 1 includes the number n (where n is a natural number) of transistors M1, M2, M3, M4, M5, . . . , M(n−2), M(n−1), and Mn. These transistors may be field effect transistors (FET) such as n-channel metal oxide semiconductor (MOS) transistors. Throughout this specification, the same applies to all the other structural components that are referred to as “transistors”, unless otherwise specified. In FIG. 2, the first end and second end of the switch circuit 1 are respectively indicated as a terminal IN and a terminal OUT.

The switch circuit 1 further includes resistors Rg1, Rg2, Rg3, Rg4, Rg5, . . . , Rg(n−2), Rg(n−1), and Rgn, and resistors Rb1, Rb2, Rb3, Rb4, . . . , Rb(n−2), Rb(n−1), and Rbn. The switch circuit 1 further includes resistors Rds(1,1), Rds(1,2), Rds(2,1), Rds(2,2), Rds(3,1), Rds(3,2), Rds(4,1), Rds(4,2), Rds(5,1), Rds(5,2), . . . , Rds(n−2,1), Rds(n−2,2), Rds(n−1,1), Rds(n−1,2), Rds(n,1), and Rds(n,2).

For the resistors Rds(1,1), Rds(1,2), Rds(2,1), Rds(2,2), Rds(3,1), Rds(3,2), Rds(4,1), Rds(4,2), Rds(5,1), Rds(5,2), . . . , Rds(n−2,1), Rds(n−2,2), Rds(n−1,1), Rds(n−1,2), Rds(n,1), and Rds(n,2), all of the resistance values thereof are substantially R1. In the following description, it is assumed that the resistance values of these resistors Rds are substantially equal.

The transistors M1, M2, M3, M4, M5, . . . , M(n−2), M(n 1), and Mn are coupled in series between the terminal IN and terminal OUT. In particular, the terminal IN is coupled to the first end of the transistor M1, and the second end of the transistor M1 is coupled to the first end of the transistor M2. The second end of the transistor M2 is coupled to the first end of the transistor M3, and the second end of the transistor M3 is coupled to the first end of the transistor M4. The same applies to the connections of the transistors M4, M5, . . . , M(n−2), M(n−1), and Mn. The second end of the transistor Mn is coupled to the terminal OUT.

The resistor Rg1 is coupled between the gate (hereinafter this may also be referred to as a “control end”) of the transistor M1 and the gate of the transistor M2. The resistor Rg2 is coupled between the gate of the transistor M2 and the gate of the transistor M3. The resistor Rg3 is coupled between the gate of the transistor M3 and the gate of the transistor M4. The same applies to the resistors Rg4, Rg5, . . . , Rg(n−2), and Rg(n−1). The gate of the transistor Mn is coupled to one end of the resistor Rgn. The other end of the resistor Rgn is coupled to a node to which a signal GB is input. FIG. 2 shows a control end through which a signal GB is input to the switch circuit 1. The signal GB may be the control signal CNT1 discussed with reference to FIG. 1. The signal GB can be switched by the control circuit 7 between the high (H) level and low (L) level. Throughout the specification, the term “level” indicates a voltage level, unless otherwise specified.

The resistor Rb1 is coupled between the body (hereinafter this may also be referred to as a “backgate”) of the transistor M1 and the body of the transistor M2. The resistor Rb2 is coupled between the body of the transistor M2 and the body of the transistor M3. The resistor Rb3 is coupled between the body of the transistor M3 and the body of the transistor M4. The same applies to the resistors Rb4, . . . , Rb(n−2), and Rb(n−1). The body of the transistor Mn is coupled to one end of the resistor Rbn. The other end of the resistor Rbn is coupled to a node through which a signal BB is input. FIG. 2 further shows the control end through which a signal BB is input into the switch circuit 1. The signal BB may be supplied by the control circuit 7. The voltage of the signal BB is set in accordance with the voltage of the signal GB.

The first end of the transistor M1 is coupled to one end of the resistor Rds(1,1), the other end of the resistor Rds(1,1) is coupled to one end of the resistor Rds(1,2), and the other end of the resistor Rds(1,2) is coupled to the second end of the transistor M1. The first end of the transistor M2 is coupled to one end of the resistor Rds(2,1), the other end of the resistor Rds(2,1) is coupled to one end of the resistor Rds(2,2), and the other end of the resistor Rds(2,2) is coupled to the second end of the transistor M2. The first end of the transistor M3 is coupled to one end of the resistor Rds(3,1), the other end of the resistor Rds(3,1) is coupled to one end of the resistor Rds(3,2), and the other end of the resistor Rds(3,2) is coupled to the second end of the transistor M3. The same applies to the resistors Rds(4,1), Rds(4,2), Rds(5,1), Rds(5,2), . . . , Rds(n−2,1), Rds(n−2,2), Rds(n−1,1), Rds(n−1,2), Rds(n,1), and Rds(n,2).

Each of the resistors Rg, Rb, and Rds may be formed by using polysilicon, for example.

The switch circuit 1 may further include, as structural components of the feedback circuit, transistors Tr(1,3), Tr(1,4), Tr(2,1), Tr(2,2), Tr(2,3), Tr(2,4), Tr(3,1), Tr(3,2), Tr(3,3), Tr(3,4), Tr(4,1), Tr(4,2), Tr(4,3), Tr(4,4), Tr(5,1), Tr(5,2), Tr(5,3), Tr(5,4), Tr(n−2,1), Tr(n−2,2), Tr(n−2,3), Tr(n−2,4), Tr(n−1,1), Tr(n−1,2), Tr(n−1,3), Tr(n−1,4), Tr(n,1), and Tr(n,2).

The transistors Tr(1,3) and Tr(1,4) correspond to the transistor M1.

The first end of the transistor Tr(1,3) is coupled to the body of the transistor M1, and the gate of the transistor Tr(1,3) is coupled to the gate of the transistor M1. The second end of the transistor Tr(1,3) is coupled to the first end of the transistor Tr(1,4) and to the gate of the transistor Tr(1,4). That is, the second end of the transistor Tr(1,3) is coupled to the diode-connected transistor Tr(1,4). The second end of the transistor Tr(1,4) is coupled to a node mutually coupling the resistor Rds(2,1) and the resistor Rds(2,2).

The following holds when the integer k is any integer between 2 to n−1.

The transistors Tr(k,1), Tr(k,2), Tr(k,3), and Tr(k,4) correspond to the transistor Mk.

The first end of the transistor Tr(k,1) is coupled to the body of the transistor Mk, and the gate of the transistor Tr(k,1) is coupled to the gate of the transistor Mk. The second end of the transistor Tr(k,1) is coupled to the first end of the transistor Tr(k,2) and to the gate of the transistor Tr(k,2). That is, the second end of the transistor Tr(k,1) is coupled to the diode-connected transistor Tr(k,2). The second end of the transistor Tr(k,2) is coupled to a node mutually coupling the resistor Rds(k−1,1) and the resistor Rds(k−1,2).

The first end of the transistor Tr(k,3) is coupled to the body of the transistor Mk, and the gate of the transistor Tr(k,3) is coupled to the gate of the transistor Mk. The second end of the transistor Tr(k,3) is coupled to the first end of the transistor Tr(k,4) and to the gate of the transistor Tr(k,4). That is, the second end of the transistor Tr(k,3) is coupled to the diode-connected transistor Tr(k,4). The second end of the transistor Tr(k,4) is coupled to a node mutually coupling the resistor Rds(k+1,1) and the resistor Rds(k+1,2).

The transistors Tr(n,1) and Tr(n,2) correspond to the transistor Mn.

The first end of the transistor Tr(n,1) is coupled to the body of the transistor Mn, and the gate of the transistor Tr(n,1) is coupled to the gate of the transistor Mn. The second end of the transistor Tr(n,1) is coupled to the first end of the transistor Tr(n,2) and to the gate of the transistor Tr(n,2). That is, the second end of the transistor Tr(n,1) is coupled to the diode-connected transistor Tr(n,2). The second end of the transistor Tr(n,2) is coupled to a node mutually coupling the resistor Rds(n−1,1) and the resistor Rds(n−1,2).

With the signal GB being at an H level, the transistors M1, M2, M3, M4, M5, . . . , M(n−2), M(n−1), and Mn are in the ON state, which means that the switch circuit 1 is in the ON state.

With the signal GB being at an L level, the transistors M1, M2, M3, M4, M5, . . . , M(n−2), M(n−1), and Mn are in the OFF state, which means that the switch circuit 1 is in the OFF state. With the switch circuit 1 being in the OFF state, the voltage applied between the terminal IN and terminal OUT is divided due to the above-mentioned coupling relationship of the resistors Rds, and the divided voltages are individually applied to the transistors M1, M2, M3, M4, M5, . . . , M(n−2), M(n−1), and Mn. The voltages applied to the transistors M1, M2, M3, M4, M5, . . . , M(n−2), M(n−1), and Mn are substantially equal to each other.

If the potential (hereinafter this may also be referred to as a “voltage”) at the body of the transistor M2 is higher than the voltage at the second end of the transistor Tr(2,2), a current flows from the body via the transistors Tr(2,1) and Tr(2,2) during the ON state of the transistors Tr(2,1) and Tr(2,2). With such a current flow, the voltage of the body decreases. Whether the transistor Tr(2,1) is in the ON state or in the OFF state depends on the voltage at the gate of the transistor M2. This is why the gate of the transistor Tr(2,1) is coupled to the gate of the transistor M2.

If the voltage at the body of the transistor M2 is higher than the voltage at the second end of the transistor Tr(2,4), a current flows from the body via the transistors Tr(2,3) and Tr(2,4) during the ON state of the transistors Tr(2,3) and Tr(2,4). With such a current flow, the voltage of the body decreases. Whether the transistor Tr(2,3) is in the ON state or in the OFF state depends on the voltage at the gate of the transistor M2. This is why the gate of the transistor Tr(2,3) is coupled to the gate of the transistor M2.

The above description relates to the transistors Tr(2,1), Tr(2,2), Tr(2,3), and Tr(2,4) that correspond to the transistor M2. The same holds for the transistors Tr that correspond to other transistors M.

In the above description, the second end of the transistor Tr(2,2), for example, is coupled to the node mutually coupling the resistor Rds(1,1) and resistor Rds(1,2). If the resistance value of the resistor Rds(1,1) is extremely small, this coupling relationship may be interpreted as the second end of the transistor Tr(2,2) being coupled to the first end of the transistor M1 without any resistor intervening. If the resistance value of the resistor Rds(1,1) is extremely small, the resistance value of the resistor Rds(1,2) will differ from the resistance value of the resistor Rds(1,1). The same holds for other transistors Tr having similar connections.

In the above description, the transistor Tr(2,1) having the gate coupled to the gate of the transistor M2 and the transistor Tr(2,2) having a diode connection are coupled in this order in the path between the body of the transistor M2 and the first end of the transistor M1. The present embodiment, however, is not limited thereto. The transistor Tr(2,1) and the transistor Tr(2,2) may be coupled in the reverse order in the path between the body of the transistor M2 and the first end of the transistor M1. The same holds for other transistors Tr having similar connections.

As the structural components of the switch circuit 1, diode-connected transistors such as the transistors Tr(1,4), Tr(2,2), Tr(2,4), Tr(3,2), Tr(3,4), . . . , Tr(n−1,2), Tr(n−1,4), and Tr(n,2) have been discussed. In the switch circuit 1, a diode formed from a PN junction may be adopted in place of these transistors Tr. The same holds for other diode-connected transistors described in this specification. Throughout this specification, a “diode” is intended to indicate possible use of both a diode-connected transistor and a PN junction diode. Whichever is used, the electrodes of the diode will be referred to as an anode and a cathode throughout the specification.

In the above description, a transistor M is associated with a transistor on the circuit diagram, as a structural element of the switch circuit 1. The transistor M may be implemented as a plurality of transistors. For instance, the transistor M may be implemented as a plurality of transistors coupled in series or in parallel to each other.

### <1-2> Layout

### <1-2-1> Overview of Layout

The overview of the layout of transistors included in the switch circuit 1 will be described.

Throughout the specification, the layout of the transistor M1, transistor Mk, transistor Mn, transistor Tr(1,3), transistor Tr(k,1), transistor Tr(k,3), and transistor Tr(n,1) (where k is an integer between 2 and n−1) will be focused on.

The transistors M1, Mk, and Mn are switches that pass or block a signal, and are protected by a feedback circuit. The transistors Tr(1,3), Tr(k,1), Tr(k,3), and Tr(n,1) have gates coupled to the gates of the respective transistors M. The transistors Tr(1,3), Tr(k,1), Tr(k,3), and Tr(n,1) determine whether or not the feedback circuit should be turned on or off. The layout can be suitably designed so as to improve the operational reliability of the switch circuit 1.

The diode-connected transistors Tr(1,4), Tr(k,2), Tr(k,4), and Tr(n,2), and the resistors Rg, Rb, and Rds are arranged in a region different from the region of the layout described in the present embodiment. The layout for the diode-connected transistors Tr(1,4), Tr(k,2), Tr(k,4), and Tr(n,2) and the resistors Rg, Rb, and Rds is omitted from the description here.

In the following descriptions of the drawings, a plane defined by the X direction and Y direction corresponds to a plane parallel to the surface of a semiconductor substrate on which the switch circuit 1 is arranged. The Z direction corresponds to a direction perpendicular to the substrate of the semiconductor substrate.

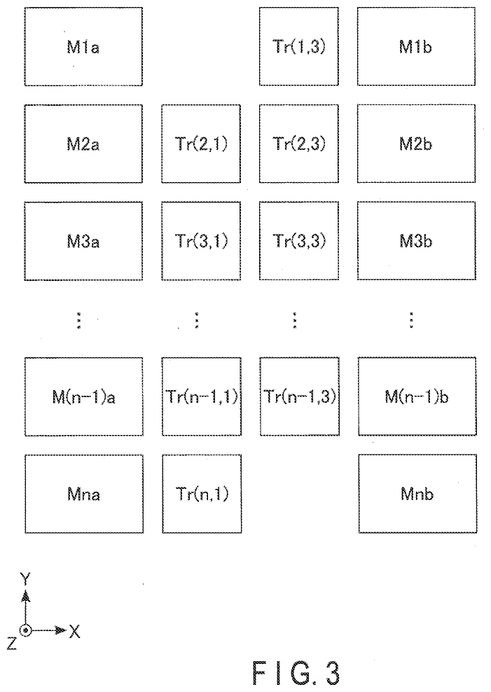

FIG. 3 is a plan view for providing an overview of the arrangement of transistors included in the switch circuit according to the first embodiment. As illustrated in FIG. 3, transistors M and transistors Tr whose gates are coupled to the gates of the respective transistors M are aligned in the X direction, and the aligned sets are aligned in the Y direction in the layout of the switch circuit 1.

The transistor M1 may be divided into at least two transistors. In particular, a transistor M1a and a transistor M1b that are coupled to each other in parallel realize the implementation of the transistor M1. The transistor Tr(1,3) having a gate coupled to the gate of the transistor M1 is interposed between the transistors M1a and M1b in the X direction. In other words, the transistors M1a and M1b and the transistor Tr(1,3) are aligned in the X direction.

The following holds when the integer k is any integer between 2 to n−1. A transistor Mk is divided into at least two transistors. In particular, a transistor Mka and a transistor Mkb that are coupled to each other in parallel realize the implementation of the transistor Mk. The transistors Tr(k,1) and Tr(k,3) each having a gate coupled to the gate of the transistor Mk are interposed between the transistors Mka and Mkb in the X direction. In other words, the transistors Mka and Mkb and the transistors Tr(k,1) and Tr(k,3) are aligned in the X direction. Such aligned sets are aligned in the Y direction for the integer k being between 2 and n−1, following the aligned set of the transistors M1a and M1b and transistor Tr(1,3).

A transistor Mn is divided into at least two transistors. In particular, the implementation of the transistor Mn is realized by a transistor Mna and a transistor Mnb that are coupled to each other in parallel. The transistor Tr(n,1) having a gate coupled to the gate of the transistor Mn is interposed between the transistors Mna and Mnb in the X direction. In other words, the transistors Mna and Mnb and the transistor Tr(n,1) are aligned in the X direction. Such aligned sets are aligned in the Y direction, together with the aligned set of the transistors M(n−1)a and M(n−1)b and transistors Tr(n−1,1) and Tr(n−1,3).

That is, part of the switch circuit 1 is implemented.

### <1-2-2> Basic Structure of Transistor

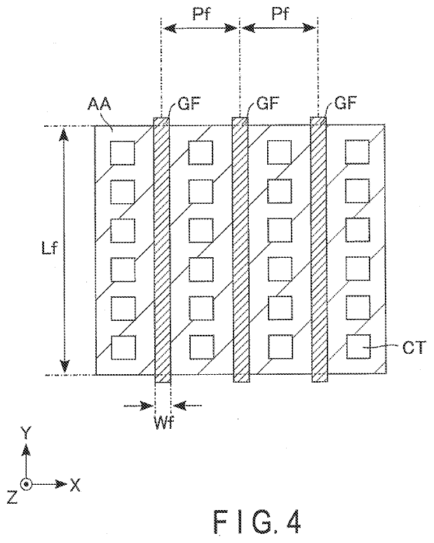

The layout described with reference to FIG. 3 may be realized in multiple patterns. These patterns differ in combinations of the basic structures applied to the transistors. The basic structure of a transistor applied in each pattern will be explained below. FIGS. 4 to 6 are plan views for respectively explaining a basic structure of a transistor included in the switch circuit according to the first embodiment. In the following description, the exemplary basic structures illustrated in FIGS. 4 to 6 will be respectively referred to as type A, type B, and type C.

The basic structure of type A will be described with reference to FIG. 4. The basic structure of type A includes an active region AA, a plurality of conductors GF, and a plurality of contacts CT.

The active region AA is formed into a rectangle.

The conductors GF are aligned in the X direction, and respectively extend in the Y direction in such a manner as to overlap the active region AA. A conductor GF functions as a gate electrode. The conductors GF are also referred to as gate fingers. The finger pitch Pf represents the alignment pitch of the conductors GF in the X direction.

Regions of the active region AA that overlap the conductors GF function as a channel of the transistor. With regard to a region that one conductor GF and the active region AA overlap, the width of this region in the X direction will be referred to as a finger width Wf of the gate finger, and the length of the region in the Y direction will be referred to as a finger length Lf of the gate finger.

Regions of the active region AA that do not overlap the conductors GF function as a source or drain. A plurality of contacts CT are provided in the source/drain regions.

After the above arrangement is determined, the gate electrodes are commonly coupled, the source regions are commonly coupled, and the drain regions are commonly coupled, with interconnects that are not shown. The structure of FIG. 4 can thereby function as one transistor.

The gate length Lg of the type-A transistor corresponds to the finger width Wf of a gate finger. The gate width Wg of the type-A transistor corresponds to the finger length Lf of the gate finger multiplied by the number of gate fingers that are commonly coupled.

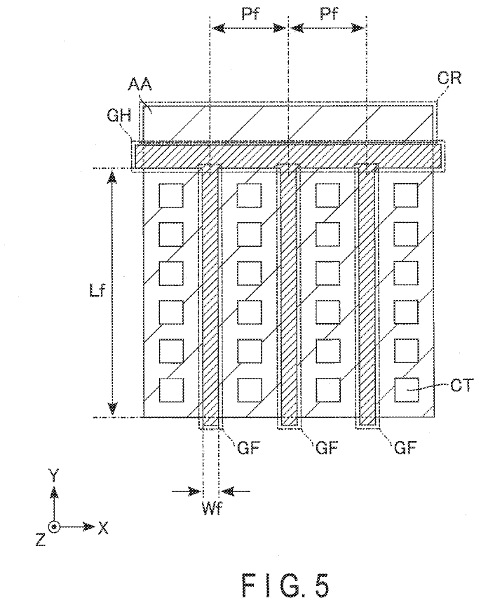

The basic structure of type B will be described with reference to FIG. 5. The basic structure of type B includes an active region AA, a plurality of conductors GF, a conductor GH, and a plurality of contacts CT.

The active region AA is formed into a rectangle.

The conductors GF are aligned with a finger pitch Pf in the X direction, and respectively extend in the Y direction in such a manner as to overlap the active region AA.

The conductor GH extends in the X direction in such a manner as to overlap the active region AA and traverse the active region AA. One end of each of the conductors GF is coupled to the conductor GH.

The conductors GF and GH function as a gate electrode. Of the active region AA, the regions that overlap the conductors GF function as a channel of the transistor. With regard to a region that one conductor GF and the active region AA overlap, the width of this region in the X direction will be referred to as a finger width Wf of the gate finger, and the length of the region in the Y direction will be referred to as a finger length Lf of the gate finger.

The regions of the active region AA that do not overlap the conductors GF or GH and are positioned on the conductor GF side in the Y direction when viewed from the conductor GH side function as a source or drain. A plurality of contacts CT are provided in the source/drain regions.

The portion of the active region AA that does not overlap the conductors GF or GH and is positioned on a side opposite the conductor GF side in the Y direction when viewed from the conductor GH side is used as a contact portion CR. In this contact portion CR, a contact for coupling to the body of the transistor is provided.

After the above arrangement is determined, the gate electrodes are commonly coupled, the source regions are commonly coupled, and the drain regions are commonly coupled, with interconnects that are not shown. The structure of FIG. 5 can thereby function as one transistor.

The gate length Lg of the type-B transistor corresponds to the finger width Wf of a gate finger. The gate width Wg of the type-B transistor corresponds to the finger length Lf of the gate finger multiplied by the number of gate fingers that are commonly coupled.

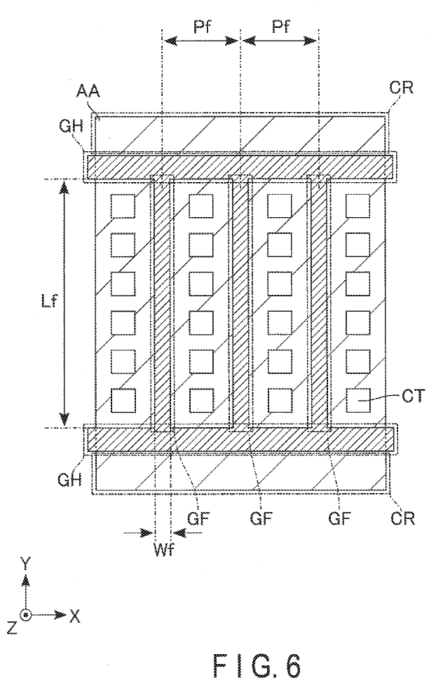

The basic structure of type C will be described with reference to FIG. 6. The basic structure of type C includes an active region AA, a plurality of conductors GF, two conductors GH, and a plurality of contacts CT.

The active region AA is formed into a rectangle.

The conductors GF are aligned with a finger pitch Pf in the X direction, and respectively extend in the Y direction in such a manner as to overlap the active region AA.

The two conductors GH are aligned in the Y direction and respectively extend in the X direction in such a manner as to overlap the active region AA and traverse the active region AA. One end of each of the conductors GF is coupled to one conductor GH. The other end of each of the conductors GF is coupled to the other conductor GH.

The conductors GF and GH function as gate electrodes. Of the active region AA, the regions that overlap the conductors GF function as a channel of the transistor. With regard to a region that one conductor GF and the active region AA overlap, the width of this region in the X direction will be referred to as a finger width Wf of the gate finger, and the length of the region in the Y direction will be referred to as a finger length Lf of the gate finger.

The portions of the active region AA that do not overlap the conductors GF or GH and are positioned between the two conductors GH in the Y direction function as a source or drain. A plurality of contacts CT are provided in the source/drain regions.

The portions of the active region AA that do not overlap the conductors GF or GH and are positioned outside the two conductors GH with respect to the Y direction are used as contact portions CR. A contact for coupling to the body of the transistor is provided in these contact portions CR.

After the above arrangement is determined, the gate electrodes are commonly coupled, the source regions are commonly coupled, and the drain regions are commonly coupled, with interconnects that are not shown. The structure of FIG. 6 can thereby function as one transistor. The gate length Lg of the type-C transistor corresponds to the finger width Wf of a gate finger. The gate width Wg of the type-C transistor corresponds to the finger length Lf of the gate finger multiplied by the number of gate fingers that are commonly coupled.

In the examples of FIGS. 4 to 6, the transistor of any of type A, type B, and type C includes three gate fingers. The number of gate fingers in a transistor, however, is not limited to three, and can be set to any number.

### <1-2-3> Examples for Layout

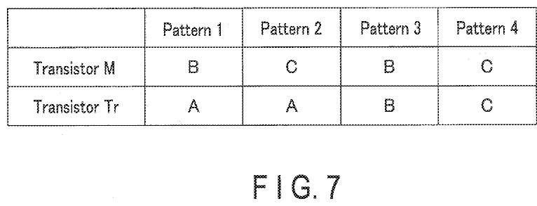

Next, exemplary patterns for the layout of FIG. 3 will be described. FIG. 7 is a table showing combinations of types of transistors implemented on the switch circuit according to the first embodiment. In the example of FIG. 7, four patterns that realize the layout of FIG. 3 using transistors of types A, B, and C are presented.

In pattern 1, type-B transistors are adopted to implement the transistors M, while type-A transistors are adopted to implement the transistors Tr.

In pattern 2, type-C transistors are adopted to implement the transistors M, while type-A transistors are adopted to implement the transistors Tr.

In pattern 3, type-B transistors are adopted to implement the transistors M, and type-B transistors are also adopted to implement the transistors Tr.

In pattern 4, type-C transistors are adopted to implement the transistors M, and type-C transistors are also adopted to implement the transistors Tr.

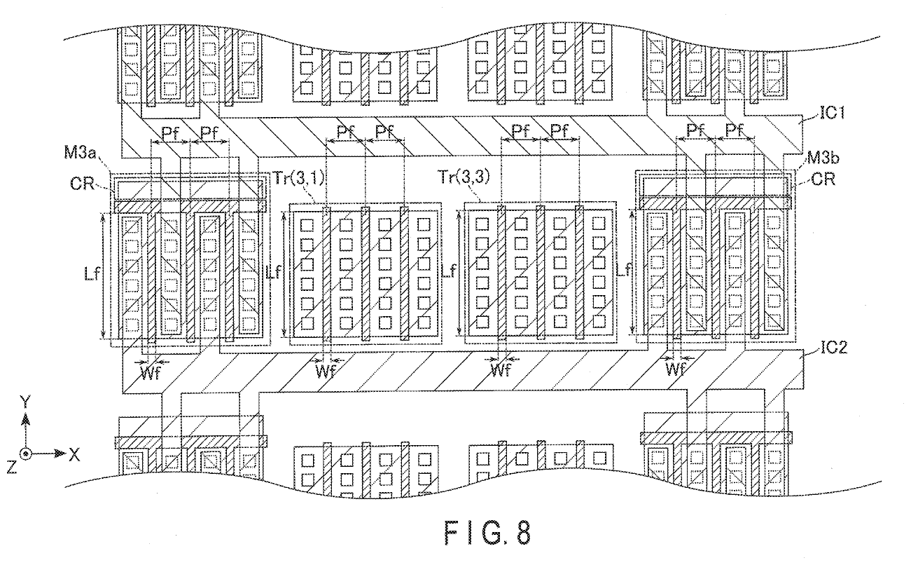

FIG. 8 is a plan view for showing a partial planar layout of a switch circuit in pattern 1 according to the first embodiment. The transistor M3a, transistor Tr(3,1), transistor Tr(3,3), and transistor M3b are aligned in this order in the X direction and spaced apart from each other. The transistors M3a and M3b are type-B transistors, and the transistors Tr(3,1) and Tr(3,3) are type-A transistors. The transistors M3a, Tr(3,1), Tr(3,3), and M3b have the same finger pitch Pf, same finger length Lf and same finger width Wf for the gate fingers.

The coupling in FIG. 8 will be described. The drain of the transistor M3a and the drain of the transistor M3b are coupled by an interconnect IC1. The interconnect IC1 is provided to couple the source of a transistor M2 to the drain of a transistor M3. The source of the transistor M3a is coupled to the source of the transistor M3b by an interconnect IC2. The interconnect IC2 is provided to couple the source of a transistor M3 to the drain of a transistor M4.

The coupling that is not shown in FIG. 8 will be explained. The gate of the transistor M3a, the gate of the transistor Tr(3,1), the gate of transistor Tr(3,3), and the gate of transistor M3b are coupled to each other by contacts and interconnects that are not shown. The contact portion CR of the transistor M3a, the drain of the transistor Tr(3,1), the drain of the transistor Tr(3,3), and the contact portion CR of the transistor M3b are coupled to each other by contacts and interconnects that are not shown.

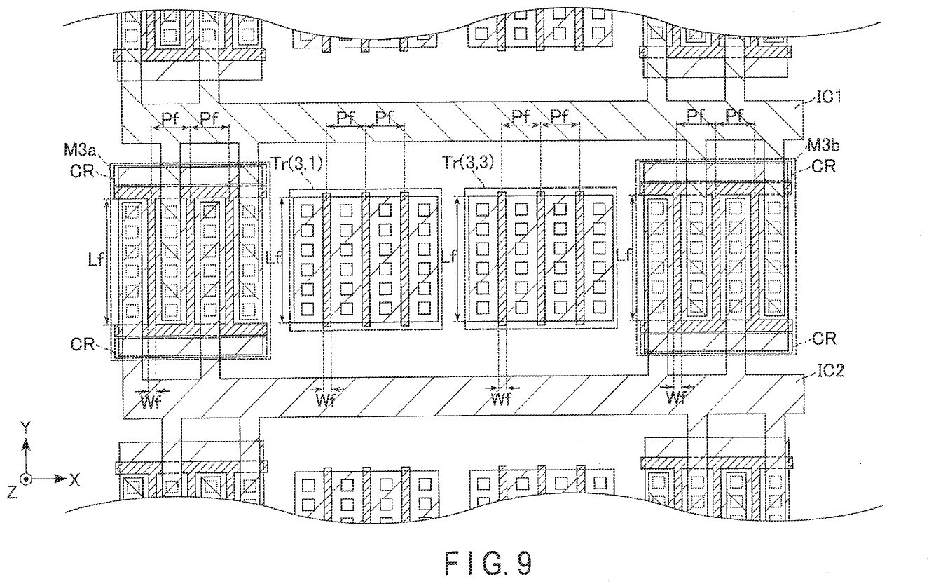

FIG. 9 is a plan view for showing a partial planar layout of a switch circuit in pattern 2 according to the first embodiment. The transistors M3a and M3b are type-C transistors. The rest of the structure is the same as that of FIG. 8.

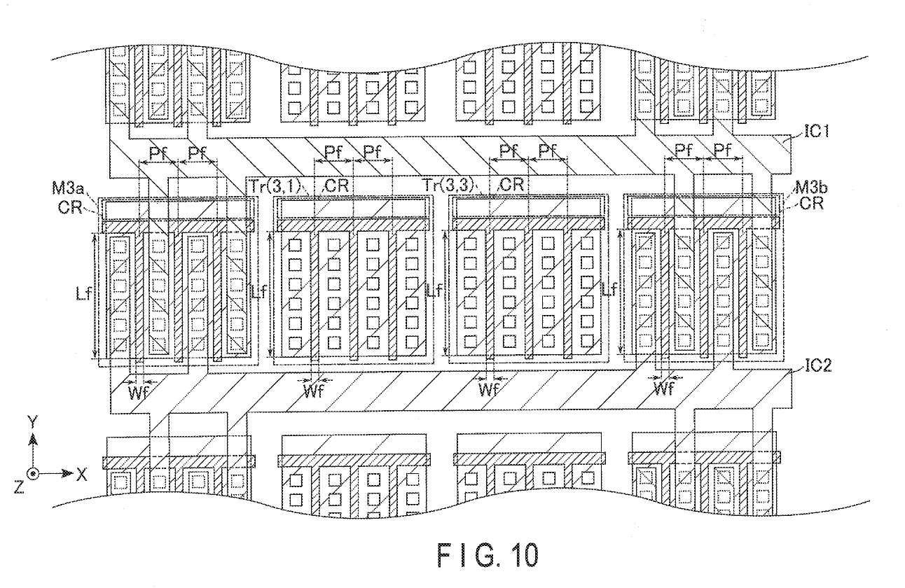

FIG. 10 is a plan view for showing a partial planar layout of a switch circuit in pattern 3 according to the first embodiment. The transistors M3a and M3b and transistors Tr(3,1) and Tr(3,3) are type-B transistors. The rest of the structure is the same as that of FIG. 8.

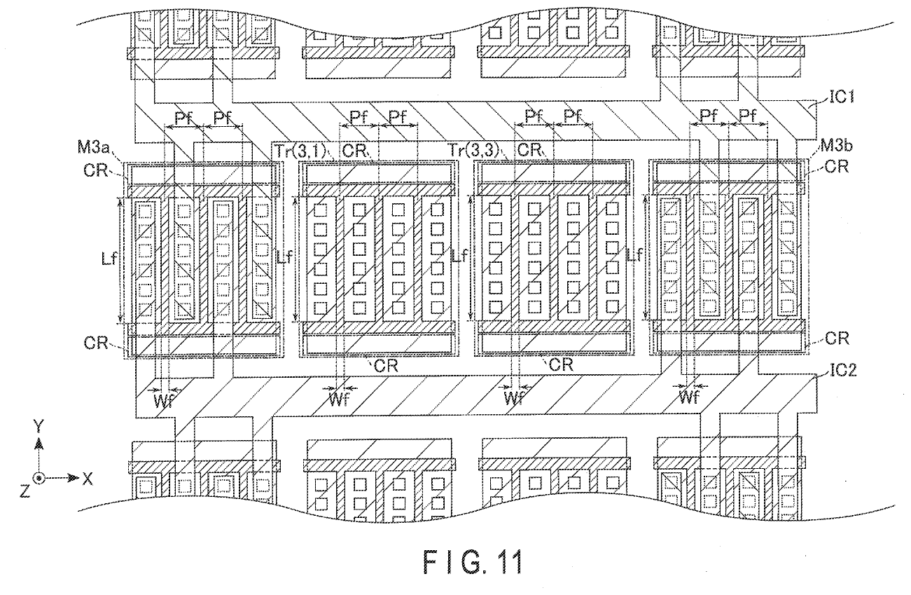

FIG. 11 is a plan view for showing a partial planar layout of a switch circuit in pattern 4 according to the first embodiment. The transistors M3a and M3b and transistors Tr(3,1) and Tr(3,3) are type-C transistors. The rest of the structure is the same as that of FIG. 8.

### <1-3> Advantageous Effects

The switch circuit 1 includes transistors M operating as a switch to pass or block a high-frequency signal, and transistors Tr operating as a feedback circuit.

The withstand voltages of the transistors M may vary in accordance with variations at the time of manufacture. The threshold voltages of the transistors Tr may also vary in accordance with variations at the time of manufacture. For instance, if the withstand voltage of a transistor M decreases and the threshold voltage of the transistor Tr increases, an input of power at a level high enough to activate the feedback circuit may cause breakage of the transistor M before the feedback circuit is actually activated.

In the switch circuit 1 according to the first embodiment, transistors having the same finger pitch, same finger length, and same finger width for the gate fingers are adopted and arranged such that the transistors Tr are interposed between the transistors M.

That is, in the switch circuit according to the first embodiment, the transistors M have properties substantially equal to the properties of the transistors Tr, and the withstand voltage of the transistors M exhibits a correlation with the threshold voltage of the transistors Tr. In particular, if the withstand voltage of the transistors M decreases, the threshold voltage of the transistors Tr also decreases. If the withstand voltage of the transistors M increases, the threshold voltage of the transistors Tr also increases. As a result, the switch circuit according to the first embodiment can prevent the breakage of the switch circuit and can improve the operational reliability.

In the pattern 3 and pattern 4 for a combination of transistors, both transistors M and transistors Tr have a contact portion CR. This brings the properties of the transistors M and transistors Tr closer to each other in the pattern 3 and pattern 4, as a result of which the breakage of the switch circuit can be prevented and the operational reliability can be improved.

### <2> Second Embodiment

The switch circuit according to the second embodiment differs from the switch circuit according to the first embodiment in the layout. The following description will focus on the features of the switch circuit according to the second embodiment that are different from the first embodiment.

### <2-1> Layout

### <2-1-1> Overview of Layout

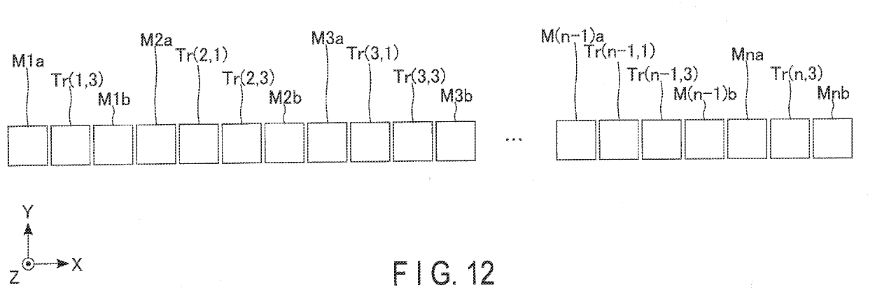

FIG. 12 is a plan view for providing an overview of the arrangement of transistors included in the switch circuit according to the second embodiment. As illustrated in FIG. 12, the transistors M and transistors Tr whose gates are coupled to the gates of the respective transistor M are aligned in the X direction, and the aligned sets are also aligned in the X direction in the layout of the switch circuit 1.

The transistor M1 may be divided into at least two transistors. In particular, a transistor M1a and a transistor M1b that are coupled to each other in parallel realize the implementation of the transistor M1. The transistor Tr(1,3) having a gate coupled to the gate of the transistor M1 is interposed between the transistors M1a and M1b in the X direction. In other words, the transistors M1a and M1b and the transistor Tr(1,3) are aligned in the X direction.

The following holds if the integer k is any integer between 2 to n−1. A transistor Mk is divided into at least two transistors. In particular, a transistor Mka and a transistor Mkb that are coupled to each other in parallel realize the implementation of the transistor Mk. The transistors Tr(k,1) and Tr(k,3) each having a gate coupled to the gate of the transistor Mk are interposed between the transistors Mka and Mkb in the X direction. In other words, the transistors Mka and Mkb and the transistors Tr(k,1) and Tr(k,3) are aligned in the X direction. Such an aligned set is repeated for an integer k that is between 2 and n−1, and is aligned in the X direction together with the set of transistors M1a and M1b and transistor Tr(1,3).

A transistor Mn is divided into at least two transistors. In particular, a transistor Mna and a transistor Mnb that are coupled to each other in parallel realize the implementation of the transistor Mn. The transistor Tr(n,1) having a gate coupled to the gate of the transistor Mn is interposed between the transistors Mna and Mnb in the X direction. In other words, the transistors Mna and Mnb and the transistor Tr(n,1) are aligned in the X direction. This aligned set is aligned in the X direction with the aligned set of the transistors M(n−1)a and M(n−1)b and transistors Tr(n−1,1) and Tr(n−1,3).

That is, part of the switch circuit 1 is implemented.

### <2-1-2> Examples for Layout

The layout described with reference to FIG. 12 may be realized in multiple patterns. These patterns take different combinations of the basic structures to be applied to the transistors. Three basic transistor structures for a pattern will be discussed in a manner similar to the first embodiment. For a combination of transistors to be implemented, four patterns indicated in FIG. 7 will be discussed in a manner similar to the first embodiment.

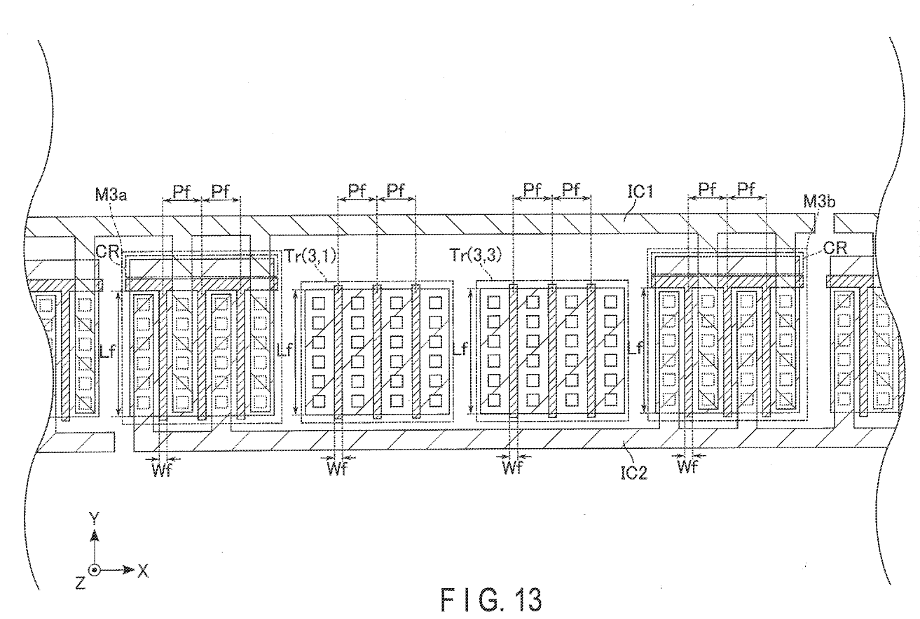

FIG. 13 is a plan view for showing a partial planar layout of a switch circuit in pattern 1 according to the second embodiment. The transistor M3a, transistor Tr(3,1), transistor Tr(3,3), and transistor M3b are aligned in this order in the X direction and spaced apart from each other. The transistors M3a and M3b are type-B transistors, and the transistors Tr(3,1) and Tr(3,3) are type-A transistors. The transistors M3a, Tr(3,1), Tr(3,3), and M3b have the same finger pitch Pf, same finger length Lf, and same finger width Wf for the gate fingers.

The coupling in FIG. 13 will be described. The drain of the transistor M3a and the drain of the transistor M3b are coupled by an interconnect IC1. The interconnect IC1 is provided to couple the source of a transistor M2 to the drain of a transistor M3. The source of the transistor M3a is coupled to the source of the transistor M3b by an interconnect IC2. The interconnect IC2 is provided to couple the source of a transistor M3 to the drain of a transistor M4.

The coupling that is not shown in FIG. 13 will be explained. The gate of the transistor M3a, the gate of the transistor Tr(3,1), the gate of transistor Tr(3,3), and the gate of transistor M3b are coupled to each other by contacts and interconnects that are not shown. The contact portion CR of the transistor M3a, the drain of the transistor Tr(3,1), the drain of the transistor Tr(3,3), and the contact portion CR of the transistor M3b are coupled to each other by contacts and interconnects that are not shown.

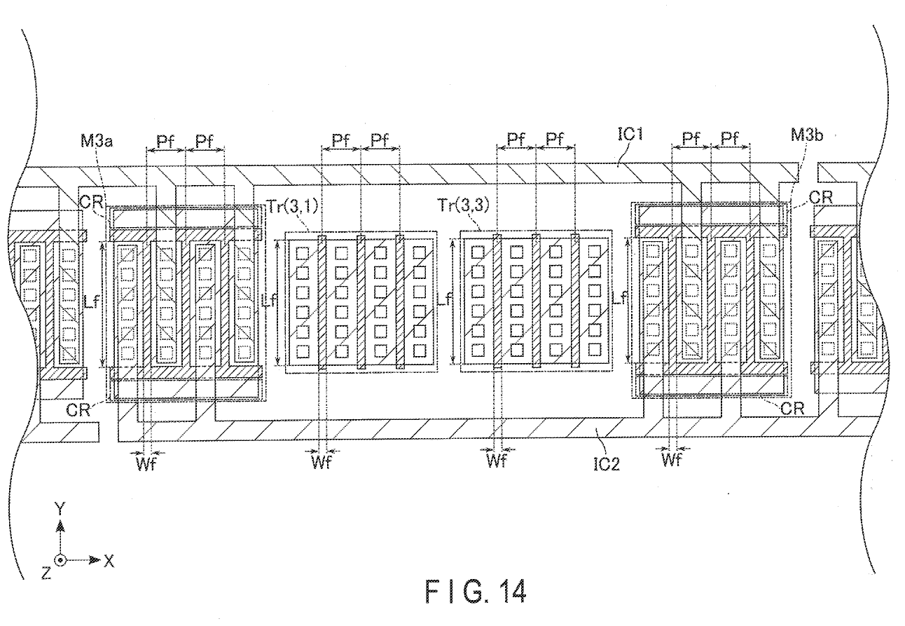

FIG. 14 is a plan view for showing a partial planar layout of a switch circuit in pattern 2 according to the second embodiment. The transistors M3a and M3b are type-C transistors. The rest of the structure is the same as that of FIG. 13.

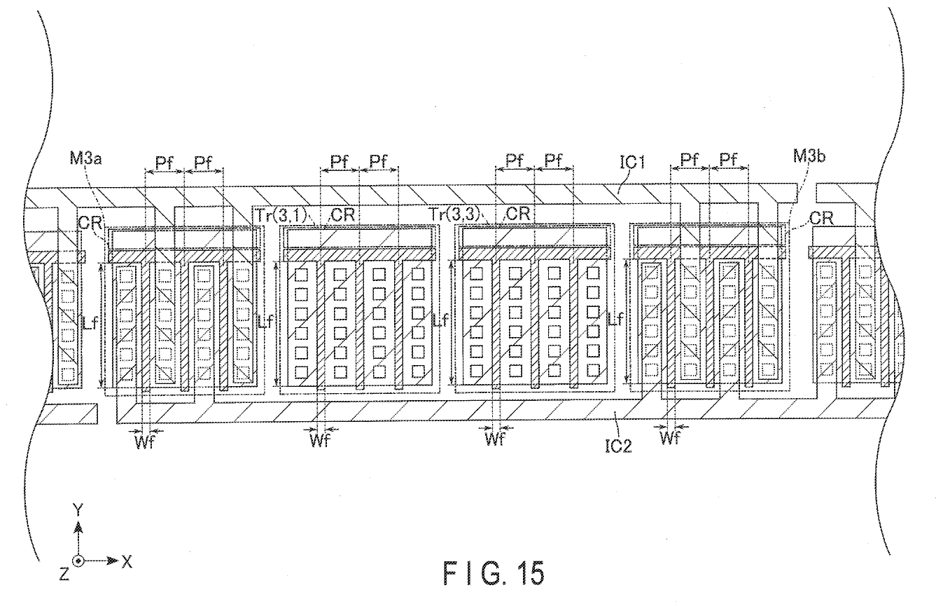

FIG. 15 is a plan view for showing a partial planar layout of a switch circuit in pattern 3 according to the second embodiment. The transistors M3a and M3b and transistors Tr(3,1) and Tr(3,3) are type-B transistors. The rest of the structure is the same as that of FIG. 13.

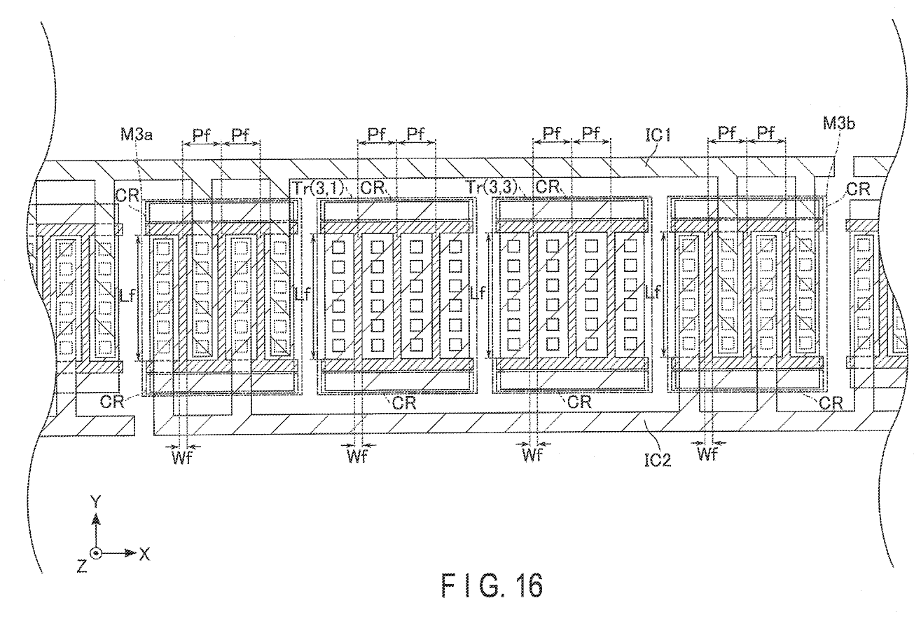

FIG. 16 is a plan view for showing a partial planar layout of a switch circuit in pattern 4 according to the second embodiment. The transistors M3a and M3b and transistors Tr(3,1) and Tr(3,3) are type-C transistors. The rest of the structure is the same as that of FIG. 13.

### <2-2> Advantageous Effects

In the switch circuit according to the second embodiment, transistors having the same finger pitch, same finger length, and same finger width for the gate fingers are adopted and arranged such that the transistors Tr are interposed between the transistors M, in the same manner as in the switch circuit according to the first embodiment.

As a result, in the switch circuit according to the second embodiment, the transistors M have properties substantially equal to the properties of the transistors Tr, and the withstand voltage of the transistors M exhibits a correlation with the threshold voltage of the transistors Tr. The switch circuit according to the second embodiment can thereby improve the operational reliability in the same manner as in the switch circuit according to the first embodiment.

### <3> Other Modifications

Throughout the specification, “coupling” refers to electrical connection. The coupling may include another element arranged in-between. Furthermore, the “resistor” in the specification may be a resistive element or a parasitic resistance element.

Throughout the specification, expressions such as “the same”, “corresponding”, “constant” and “maintaining” are used on the assumption that there may be deviations within the scope of design at the time of embodying the techniques described in the embodiments. The same applies to expressions accompanied with “substantially”, such as “substantially the same”. The expressions “supply a voltage” or “apply a voltage” are used with the intention of including both control of application or supply of a voltage, and actual application or supply of a voltage. In addition, applying or supplying a voltage may include applying or supplying a voltage of 0 volts.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising an input terminal, an output terminal, and a plurality of transistors coupled through serial coupling between the input terminal and the output terminal, wherein
the transistors include:
a first transistor having a first end and a second end that are used for the serial coupling; and
a second transistor having a third end, a fourth end, a first gate, and a first body, the third end and the fourth end being used for the serial coupling, the third end being coupled to the second end,
the semiconductor device further comprises a third transistor and a first diode serially coupled between the first body and the first end,
the third transistor includes a second gate coupled to the first gate,
an anode of the first diode is arranged on a side of the first body between the first body and the first end, and a cathode of the first diode is arranged on a side of the first end between the first body and the first end,
the second transistor includes a first sub-transistor and a second sub-transistor that are coupled in parallel with each other, and
the first transistor, the first sub-transistor, the second sub-transistor, the third transistor, and the first diode are arranged on a substrate, with the third transistor interposed between the first sub-transistor and the second sub-transistor in a first direction.

2. The semiconductor device according to claim 1, wherein
in each of the first sub-transistor, the second sub-transistor, and the third transistor, a conductor that functions as a gate electrode extends in a second direction that intersects the first direction.

3. The semiconductor device according to claim 2, further comprising:
a first resistor and a second resistor serially coupled between the first end and the second end,
wherein the third transistor and the first diode are serially coupled between the first body and a node coupling the first resistor and the second resistor.

4. The semiconductor device according to claim 3, wherein
a fourth transistor is used as the first diode,
the third transistor has a fifth end coupled to the first body, and a sixth end, and
the fourth transistor has a seventh end coupled to the sixth end, an eighth end coupled to the node coupling the first resistor and the second resistor, and a third gate coupled to the seventh end.

5. The semiconductor device according to claim 2, wherein
the transistors further include:
a fifth transistor having a ninth end and a tenth end that are used for the serial coupling, the ninth end being coupled to the fourth end,
the semiconductor device further comprises:
a sixth transistor and a second diode serially coupled between the first body and the tenth end,
the sixth transistor includes a fourth gate coupled to the first gate,
an anode of the second diode is arranged on a side of the first body between the first body and the tenth end, and a cathode of the second diode is arranged on a side of the tenth end between the first body and the tenth end, and
the fifth transistor, the sixth transistor, and the second diode are arranged on the substrate, and the sixth transistor is interposed between the first sub-transistor and the second sub-transistor in the first direction.

6. The semiconductor device according to claim 2, wherein
the first transistor includes a third sub-transistor and a fourth sub-transistor that are coupled in parallel with each other,
the third sub-transistor and the fourth sub-transistor are aligned in the first direction, and
the first sub-transistor and the third sub-transistor are aligned in the second direction.

7. The semiconductor device according to claim 2, wherein
the first transistor includes a third sub-transistor and a fourth sub-transistor that are coupled in parallel with each other, and
the first sub-transistor, the second sub-transistor, the third sub-transistor, and the fourth sub-transistor are aligned in the first direction.

8. The semiconductor device according to claim 1, wherein
in each of the first sub-transistor, the second sub-transistor, and the third transistor, a plurality of conductors that function as a gate electrode are aligned with a first pitch.

9. The semiconductor device according to claim 1, wherein
each of the first sub-transistor, the second sub-transistor, and the third transistor has a conductor that functions as a gate electrode, and the conductors of the first sub-transistor, the second sub-transistor, and the third transistor have a longer side of an equal length and a shorter side of an equal width.

10. The semiconductor device according to claim 1, wherein
each of the first sub-transistor, the second sub-transistor, and the third transistor has a conductor that functions as a gate electrode, and the conductors of the first sub-transistor, the second sub-transistor, and the third transistor extend in the same direction.

11. The semiconductor device according to claim 1, wherein
each of the first sub-transistor, the second sub-transistor, and the third transistor includes a contact portion in which a contact to be coupled to a body of a corresponding one of the first sub-transistor, the second sub-transistor, and the third transistor is provided.
